(19) United States
(12) Patent Application Publication
(10) Pub. No.: US 2026/0293647 A1
(43) Pub. Date: Sep. 24, 2026

(54) GALLIUM-NITRIDE-BASED ELECTRONIC CHIPS

(71) Applicant: STMICROELECTRONICS INTERNATIONAL N.V., Geneva (CH)

(72) Inventors: Aurore CONSTANT, Tours (FR); Sebastien AVERTIN, Esvres (FR); Pascal LE GALL, Cerelles (FR); Nossikpendou Yves SAMA, Tours (FR); Cristina TRINGALI, Augusta (IT); Antonio Filippo Massimo PIZZARDI, Misterbianco (IT); Ferdinando IUCOLANO, Gravina di Catania (IT)

(21) Appl. No.: 19/559,078

(22) Filed: Mar. 6, 2026

(30) Foreign Application Priority Data
Mar. 19, 2025 (FR) 2502770

(51) Int. Cl. H10W 20/43; H10D 30/01; H10D 30/47; H10D 84/82

(52) U.S. Cl. CPC H10W 20/43; H10D 30/015; H10D 30/472; H10D 84/82

(57) ABSTRACT

The present disclosure relates to a method for manufacturing electronic chips. An example method includes the consecutive steps: a) forming an interconnection structure on a top face of a gallium-nitride-based stack, in turn arranged on a top face of a semiconductor substrate; b) arranging a first insulating layer on the top face of the interconnection structure; c) forming a resin etching mask on the top face of the first insulating layer, then etching the first insulating layer and the interconnection structure through the resin etching mask within a peripheral region of each electronic chip up to expose the top face of the gallium-nitride-based stack; d) etching the gallium-nitride-based stack opposite the peripheral region using the first insulating layer as etching mask, up to expose the top face of the semiconductor substrate; and e) cutting the semiconductor substrate so as to singularize the electronic chips.

### CROSS REFERENCE TO RELATED APPLICATION(S)

This application claims the priority benefit of French Patent Application number 2502770, filed on Mar. 19, 2025, entitled “PUCE ÉLECTRONIQUE À BASE DE NITRURE DE GALLIUM” which is hereby incorporated by reference to the maximum extent allowable by law.

### TECHNICAL FIELD

The present disclosure relates generally to the field of electronic chips and, more particularly, the field of gallium-nitride-based electronic chips.

### BACKGROUND

In industry, most of the electronic devices are mass produced. Several electronic chips are thus currently manufactured in and on a same semiconductor substrate, for example a same plate or a semiconductor wafer. The electronic chips then can be separated, or singularized, to be usable, for example alone or in an electronic device including other components. This singularization is generally performed by cutting, for example thanks to a saw.

During this singularization, for example when cutting a semiconductor wafer, a crack can form on an edge of an electronic chip, and propagate within the chip. Such a crack can lead to a failure of electronic circuits of the electronic chip.

To protect an electronic chip, particularly during manufacturing, singularizing, or in use, the electronic chip can include, at its peripheral, means for stopping cracks.

It would be desirable to overcome at least in part some drawbacks of the known embodiments of the electronic chips.

### BRIEF SUMMARY

To this end, one embodiment provides a method for manufacturing electronic chips including the consecutive following steps:
a) forming an interconnection structure on a top face of a gallium-nitride-based stack, in turn arranged on a top face of a semiconductor substrate;
b) arranging a first insulating layer on the top face of the interconnection structure;
c) forming a resin etching mask on the top face of the first insulating layer, then etching the first insulating layer and the interconnection structure through the resin etching mask within a peripheral region of each electronic chip up to expose the top face of the gallium-nitride-based stack;
d) etching the gallium-nitride-based stack opposite the peripheral region using the first insulating layer as etching mask, up to expose the top face of the semiconductor substrate;
e) cutting the semiconductor substrate so as to singularize the electronic chips.

According to an embodiment, the manufacturing method includes, between steps d) and e), a step for forming a second insulating layer on the top face of the first insulating layer, and in the bottom and on the side flanks of the peripheral region.

According to an embodiment, the first insulating layer is made of an oxide.

According to an embodiment, the first insulating layer is deposited during step b) with a thickness in the range from 2 µm to 4 µm.

According to an embodiment, the interconnection structure has a thickness in the range from 10 µm to 15 µm.

According to an embodiment, each electronic chip includes a high electronic mobility transistor, the transistor being formed within the interconnection structure, and in and on the gallium-nitride-based stack.

According to an embodiment, each electronic chip includes a seal ring.

According to an embodiment, the interconnection structure includes a metal pad, arranged on the flank of the top face of the interconnection structure, the metal pad being covered by the first insulating layer during step b).

According to an embodiment, the metal pad corresponds to a contact recovery pad of the transistor.

According to an embodiment, etching the first insulating layer and the interconnection structure during step c) is an anisotropic etching, and etching the gallium-nitride-based stack during step d) is an anisotropic etching.

According to an embodiment, etching the first insulating layer and the interconnection structure during step c) is an isotropic etching, and etching the gallium-nitride-based stack during step d) is an anisotropic etching.

Another embodiment provides an electronic chip including:

an interconnection structure arranged on a top face of a gallium-nitride-based stack, in turn arranged on a top face of a semiconductor substrate; and

a first insulating layer on the top face of the interconnection structure, the electronic chip further including, an opening in a peripheral region, exposing the top face of the semiconductor substrate.

According to an embodiment, in openings, the side flanks of the interconnection structure are aligned with the side flanks of the gallium-nitride-based stack.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIGS. 1A, 1B, 1C, 1D, 1E, 1F, 1G and 1H are sectional, partial and schematic views of structures obtained at the end of consecutive steps of an example method for manufacturing electronic chips according to a first embodiment;

FIGS. 2A and 2B are sectional, partial and schematic views of structures obtained at the end of consecutive steps of an example method for manufacturing electronic chips according to a second embodiment;

FIGS. 3A and 3B are sectional, partial and schematic views of structures obtained at the end of consecutive steps of an example method for manufacturing electronic chips according to a third embodiment; and

FIGS. 4A and 4B are sectional, partial and schematic views of structures obtained at the end of consecutive steps of an example method for manufacturing electronic chips according to a fourth embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms "front", "back", "top", "bottom", "left", "right", etc., or to relative positional qualifiers, such as the terms "above", "below", "higher", "lower", etc., or to qualifiers of orientation, such as "horizontal", "vertical", etc., reference is made to the orientation shown in the figures.

Unless specified otherwise, the expressions "around", "approximately", “substantially” and "in the order of" signify within 10% or 10°, and preferably within 5% or 5°.

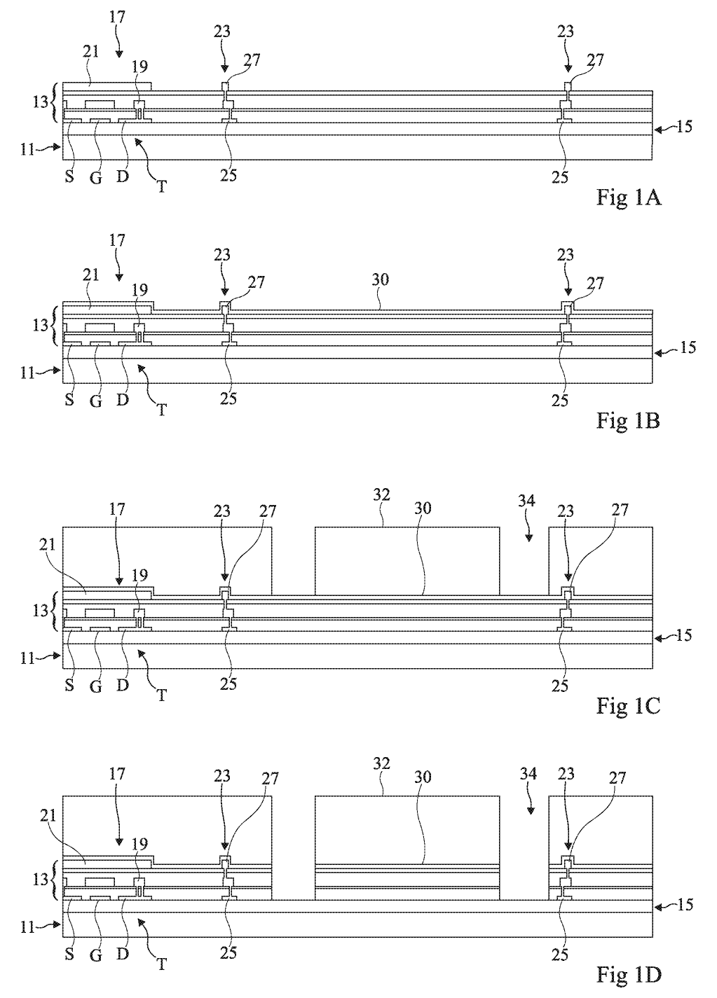

FIGS. 1A, 1B, 1C, 1D, 1E, 1F, 1G and 1H are sectional, partial and schematic views of structures obtained at the end of consecutive steps of an example method for manufacturing electronic chips according to a first embodiment.

FIG. 1A illustrates a starting structure including a semiconductor substrate 11, a gallium-nitride-based stack 15 on the semiconductor substrate 11, and an interconnection structure 13 on the gallium-nitride-based stack 15. As an example, the gallium-nitride-based stack 15 is arranged on and in contact with the top face of the semiconductor substrate 11. For example, the gallium-nitride-based stack 15 continuously extends over the whole top surface of the semiconductor substrate 11. For example, the interconnection structure is arranged on and in contact with the top face of the gallium-nitride-based stack 15.

For example, the substrate 11 is made of silicon, for example of single-crystal silicon, or of silicon carbide. Alternatively, the substrate 11 is made of aluminum nitride.

For example, the gallium-nitride-based stack 15 includes several semiconductor layers. For example, the semiconductor layers of the stack 15 are made of semiconductor materials of the III-V type based on gallium nitride (GaN), for example gallium nitride and/or aluminum-gallium nitride (AlGaN). For example, the gallium-nitride-based stack 15 has a thickness in the range from 2 µm to 10 µm, for example in the order of 5 µm.

For example, the interconnection structure 13 corresponds to a stack of insulating layers, for example dielectric layers, in which are formed, within regions of electronic circuits 17, metal tracks or pads. In FIG. 1A, four insulating layers are illustrated within the interconnection structure 13. In practice, the interconnection structure 13 can comprise a number of insulating layers higher than four. For example, the interconnection structure 13 has a thickness in the range from 10 µm to 30 µm, for example in the range from 15 µm to 18 µm.

As an example, the starting structure includes a plurality of circuit regions 17 formed in the interconnection structure 13 and the GaN stack 15. In FIG. 1A, a single circuit region 17 is illustrated. Each circuit region 17 can comprise a plurality of electric components. As an example, each circuit region 17 includes a transistor T, for example a High Electron Mobility Transistor, or HEMT.

For example, transistors T are formed in and on the GaN stack 15 and in the interconnection structure 15. As an example, each transistor T includes a source contact S, a drain contact D, and a gate contact G formed on the GaN stack 15. As an example, these contacts are coupled to metal tracks or pads 19 formed on and in the insulating layers of the interconnection structure 13. As an example, the circuit region 17 includes one or more metal pads 21 formed at the surface of the interconnection structure 13. As an example, metal pads 21 are made of aluminum, for example of aluminum and copper.

As an example, each circuit region 17 is surrounded by a seal ring 23 allowing possible cracks propagating within the circuit region 17 to be stopped and/or detected. As an example, the seal rings are formed in the structure 13. As an example, the seal rings 23 do not extend through the GaN stack 15.

As an example, each seal ring 23 includes a plurality of metal levels 25, formed on the insulating layers of the interconnection structure 13, and coupled to each other by conductive vias. As an example, each seal ring further includes a top metal level 27 formed at the surface of the interconnection structure 13. As an example, the metal levels 27 are made of aluminum, for example of aluminum and copper.

As an example, a circuit region 17 associated to a seal ring 23 surrounding it define a non-singularized electronic chip still integral with neighboring electronic chips. As an example, in the starting structure as illustrated in FIG. 1A, the electronic chips are integral with each other thanks to substrate 11, GaN stack 15, and interconnection structure 13. As an example, the electronic chips have, in the starting structure as illustrated in FIG. 1A, no electric connection between each other.

FIG. 1B illustrates a structure obtained at the end of a step for depositing an insulating layer 30, of hard mask, on the top face of the structure illustrated in FIG. 1A.

As an example, the layer 30 is deposited on the whole top face of the structure illustrated in FIG. 1A.

More particularly, during this step, the layer 30 is deposited on and in contact with the top face of the interconnection structure 13. Further, during this step, the layer 30 is for example deposited on the top face of the pads 21 and levels 27. As an example, during this step, the layer 30 is deposited in contact with the pads 21 and levels 27.

Layer 30 is for example made of a dielectric material, such as an oxide, for example Tetraethyl Orthosilicate or TEOS.

As an example, the layer 30 is conformally deposited. It is deposited with a sensibly constant thickness over its whole surface. As an example, the layer 30 is deposited with a thickness in the range from 2 µm to 4 µm, for example in the order of 3 µm.

FIG. 1C illustrates a structure obtained at the end of a step for forming a resin masking layer 32 on the top face of the structure illustrated in FIG. 1B.

More particularly, during this step, the layer 32 is formed on the entire top face of the structure illustrated in FIG. 1B. As an example, the layer 32 is formed in contact with layer 30.

The resin layer 32 is for example a photosensitive resin, for example a positive resin. For example, the layer 32 is deposited with a thickness in the range from 10 µm to 15 µm, for example in the order of 13 µm.

As an example, after being deposited, the resin layer 32 is locally removed by photolithography opposite a peripheral part of each non-singularized electronic chip.

FIG. 1D illustrates a structure obtained at the end of a step for etching the insulating layer 30 and the interconnection structure 13 of the structure illustrated in FIG. 1C trough the masking layer 32.

More particularly, during this step, the layer 30 and the structure 13 are etched so as to locally expose the top face of the GaN stack 15.

As an example, in this embodiment, etching the layer 30 and the structure 13 corresponds to an anisotropic dry etching.

During this step, the etching is for example a plasma etching.

At the end of this step, the structure includes openings 34 formed through a peripheral part of each of the non-singularized electronic chips. Openings 34 for example have their flanks aligned with the flanks of the overlying masking layer 32. As an example, at the end of this step, openings 34 have sensibly vertical flanks. As an example, at the end of this step, openings 34 have a width sensibly constant over their whole depth. Openings 34 have for example a width in the range from 15 µm to 40 µm, for example in the range from 20 µm to 25 µm.

As an example, each chip comprises an opening 34 having, in top view, a ring shape entirely surrounding the circuit region 17 and the seal ring 23 of the chip.

At the end of this step, the masking layer 32 is for example removed. After the step for removing the layer 32, the surface of the layer 30 is for example cleaned.

FIG. 1E illustrates a structure obtained at the end of a step for etching the gallium nitride stack 15 of the structure illustrated in FIG. 1D trough the masking insulating layer 30. During this step, the layer 30 acts as etching mask for stack 15.

More particularly, during this step, the stack 15 is etched so as to locally expose the top face of substrate 11.

As an example, in this embodiment, etching the stack 15 corresponds to a dry anisotropic etching.

During this step, etching is for example a plasma etching.

At the end of this step, openings 34 formed during the etching step are vertically extended through the stack 15 up to the top face of substrate 11. Openings 34 are also referred to as TGV, Through GaN Via, as they also pass vertically through the GaN-based stack 15.

As an example, at the end of this step, openings have straight flanks over their whole height. As an example, openings 34 have so no step on their side flanks between the stack 15 and the interconnection structure 13. Openings 34 are thus as wide in the plane of the top face of the interconnection structure 13 as in the plane of the bottom face of the GaN stack 15.

As an example, the layer 30 is particularly consumed during etching the GaN stack 15. Thus, at the end of this step, the layer 30 has for example a remaining thickness in the range from 0.5 µm to 3 µm, for example in the order of 1 µm.

FIG. 1F illustrates a structure obtained at the end of a step for depositing another insulating layer 36 on the top face of the structure illustrated in FIG. 1E.

More particularly, during this step, the layer 36 is formed on the top face of the layer 30, and in the bottom and on the flanks of the openings 34.

During this step, the layer 36 is formed in contact with the top face of the layer 30. During this step, the layer 36 is further in contact with the flanks of the interconnection structure 13 and with layer 30 in openings 34. During this step, the layer 36 is further in contact with the top face of the substrate 11 within the openings 34.

The layer 36 is for example a layer made of a dielectric material. As an example, layer 36 is made of an oxide, for example TEOS. Alternatively, the layer 36 is made of silicon dioxide and silicon nitride.

As an example, layer 36 is deposited with a thickness ranging from 2 µm to 10 µm, for example in the order of 5 µm.

FIG. 1G illustrates a structure obtained at the end of a step for forming a layer 37 made of a dielectric material and a encapsulation layer 38 on the top face of the structure illustrated in FIG. 1F.

More particularly, during this step, one comes forming in a first stage the dielectric material layer 37 on the top face of the structure illustrated in FIG. 1F, and more particularly on the top face of the layer 36.

As an example, the dielectric material layer 37 is made of nitride, for example silicon nitride.

As an example, the dielectric material layer 37 has a thickness less than 1.5 µm, for example less than 1 µm.

In a second stage, one comes forming the encapsulation layer 38 on the top face of the dielectric material layer 37. The layer 38 thus covers the layer 37 over the entire structure, particularly in the openings 34.

As an example, the encapsulation layer 38 is made of a dielectric material so-called Low Temperature Coating or LTC. As an example, the encapsulation layer 38 is made of polyamide, such as polyimide.

As an example, the encapsulation layer 38 is deposited with a thickness in the range from 5 µm to 15 µm, for example in the order of 7 µm.

As an example, at the end of depositing layer 38, the latter as well as layers 30 and 36 are locally removed opposite some metal pads 21 in order to allow the electric contact recovery on these same pads. In addition, the encapsulation layer 38 is removed in a portion between the peripheral openings 34 made around adjacent chips, opposite the future cutting paths individualizing the chips.

As an example, at the end of these steps for depositing and removing, a metal layer (not illustrated) is deposited on the top face of the structure, such as on the encapsulation layer 38 and in the openings leading to metal pads 21. As an example, the metal layer is made of aluminum, for example aluminum and copper.

FIG. 1H illustrates a structure obtained at the end of a step for cutting the structure illustrated in FIG. 1G so as to form single electronic chips.

More particularly, during this step, one comes forming cutting paths 39 between each of the non-singularized chips. More specifically, during this step, one comes forming cutting paths 39 between peripheral openings 34 performed around neighboring chips.

As an example, cutting paths 39 are performed by sawing. Alternatively, cutting paths 39 are performed by laser cutting.

One advantage of the present embodiment is that the openings 34 form a further seal ring allowing the propagation of cracks within the interconnection structure and within the GaN stack to be avoided or restrained.

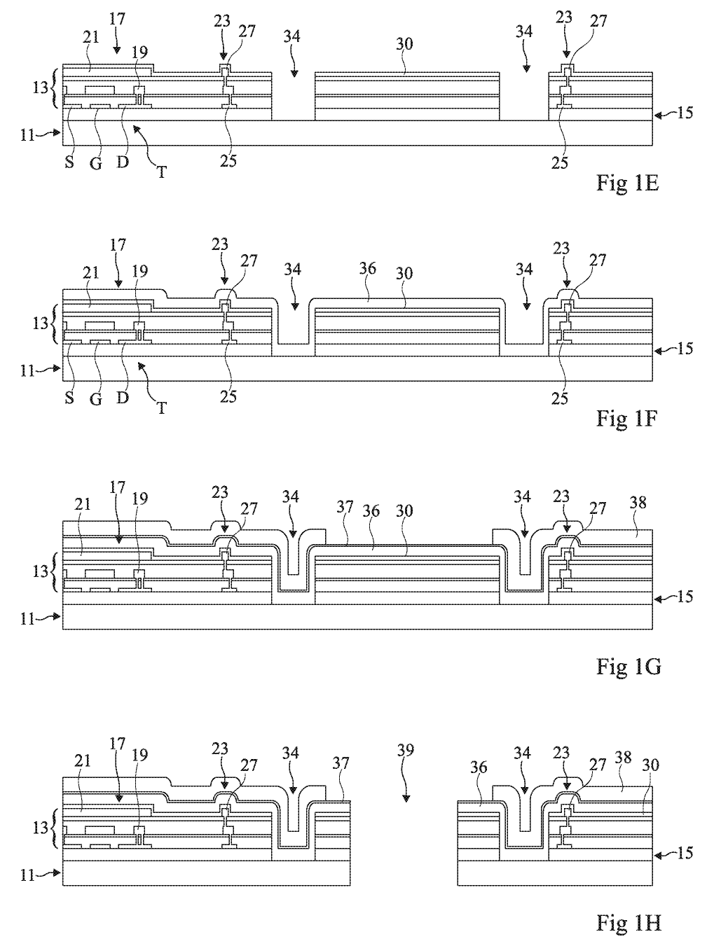

FIGS. 2A and 2B are sectional, partial and schematic views of structures obtained at the end of consecutive steps of an example method for manufacturing electronic chips according to a second embodiment.

The method for manufacturing electronic chips according to the second embodiment is similar to the method for manufacturing electronic chips according to the first embodiment, with the difference that, in the second embodiment, the step for etching the layer 30 and the interconnection structure 13 is an isotropic etching. The step for etching the GaN stack 15 is an anisotropic etching.

The method for manufacturing an electronic chip according to the second embodiment comprises exactly the steps described in relation with FIGS. 1A-C, which are not again described hereinafter.

FIG. 2A illustrates a structure obtained at the end of a step for isotropically etching the insulating layer 30 and the interconnection structure 13 of the structure illustrated in FIG. 1C through the resin layer 32.

More particularly, during this step, the layer 30 and the structure 13 are etched so as to locally expose the top face of the GaN stack 15.

During this etching, the etching is for example a wet etching.

Alternatively, the etching is during this etching, a dry etching, for example a plasma etching.

At the end of this step, the structure includes openings 34 formed in a peripheral part of each of the non-singularized electronic chips. Openings 34 have for example rounded or diagonal. In the example shown in FIG. 2A, due to the isotropy of the etching, the tops of the flanks of the apertures 34 are not aligned with the flanks of the masking layer 32. In this example, each aperture 34 extends partly under the masking layer 32. As an example, at the end of this step, the openings 34 have a width decreasing from the top face of the layer 30 up to the bottom face of the structure 13. That means the openings have a width taken in the plane of the top face of the layer 30 higher than their width taken in the plane of the bottom face of the interconnection structure 13.

At the end of this step, the masking layer 32 is for example removed. After the step for removing the masking layer 32, the surface of the layer 30 is for example cleaned.

FIG. 2B illustrates a structure obtained at the end of a step for etching the gallium nitride stack 15 of the structure illustrated in FIG. 2B through the insulating layer 30.

More particularly, during this step, the stack 15 is etched so as to locally expose the top face of the substrate 11.

As an example, in this embodiment, the etching of the stack 15 corresponds to an anisotropic etching.

During this step, the etching is for example a dry etching.

At the end of this step, from now on, openings 34 formed during the etching step extend through the stack 15 up to the top face of the substrate 11.

As an example, at the end of this step, the bottom part of each opening 34 has vertical straight flanks on its whole height. As an example, at the end of this step, the width of openings 34 is sensibly constant through the stack 15. This means that the width of openings 34 taken in the plane of the top face of the stack 15 is sensibly equal to the width of openings 34 taken in the plane of the bottom face of the stack 15.

As an example, the layer 30 is sensibly consumed when etching the GaN stack 15. Thus, at the end of this step, the layer 30 has for example a resulting width in the range from 0.5 µm to 3 µm, for example in the order of 1 µm.

After the step of etching the gallium nitride stack 15, the method continues with the steps described in relation with FIGS. 1F-H. These steps are similar to what was described in the first embodiment with the difference in the geometry of the openings 34.

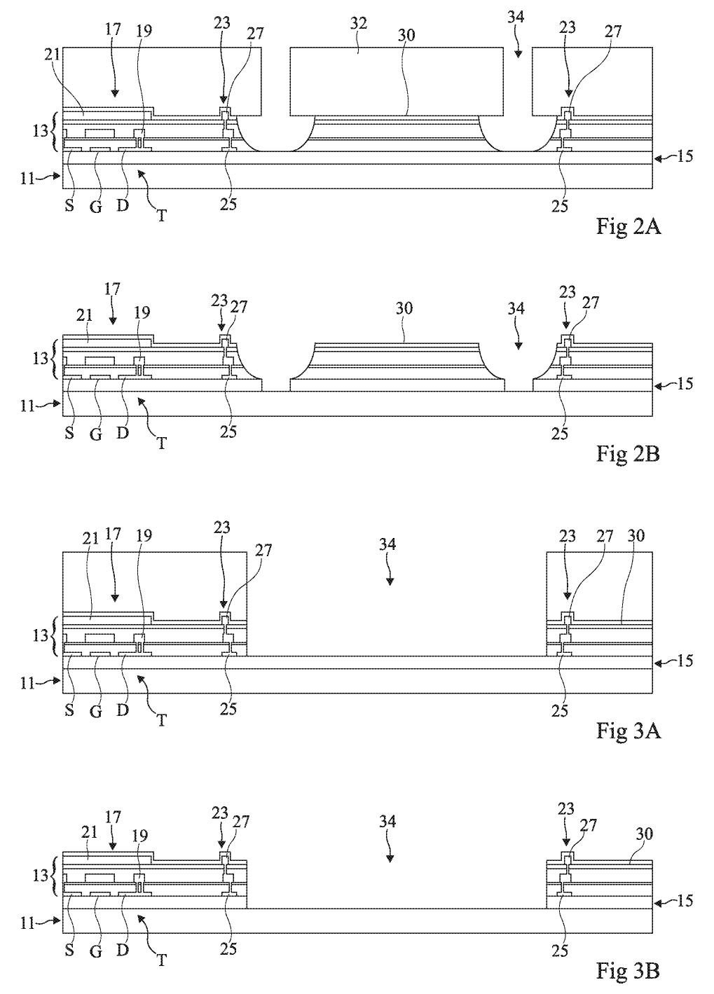

FIGS. 3A and 3B are sectional, partial and schematic views of structures obtained at the end of consecutive steps of an example method for manufacturing electronic chips according to a third embodiment.

The method for manufacturing electronic chips according to the third embodiment is similar to the method for manufacturing electronic chips according to the first embodiment with the difference that, in the third embodiment, openings 34 have a higher width so that the cutting path 39 for singularizing chips pass through the openings 34.

The method for manufacturing an electronic chip according to the third embodiment comprises exactly the steps described in relation to FIGS. 1A-C, which are not described again hereinafter.

FIG. 3A illustrates a structure obtained at the end of a step for etching the insulating layer 30 and the interconnection structure 13 of the structure illustrated in FIG. 1C through the resin layer 32.

This step is similar to those illustrated in FIGS. 1C-D with the difference that the openings 34 are not formed in a peripheral part of each of the non-singularized electronic chips but they are formed between each of the non-singularized electronic chips, and that the openings extend from a peripheral part of an electronic chip up to the peripheral part of the neighboring electronic chip.

FIG. 3B illustrates a structure obtained at the end of a step for etching the gallium nitride stack 15 of the structure illustrated in FIG. 3A through the insulating layer 30.

This step is identical to the etching step illustrated in FIG. 1E.

After the step for etching the gallium nitride stack 15, the method continues with the steps described in relation to FIGS. 1F-H. These steps are similar to what was described in the first embodiment with the difference that the geometry of the openings 34. In this embodiment, the cutting path 39 for singularizing the electronic chips is thus formed in the openings 34.

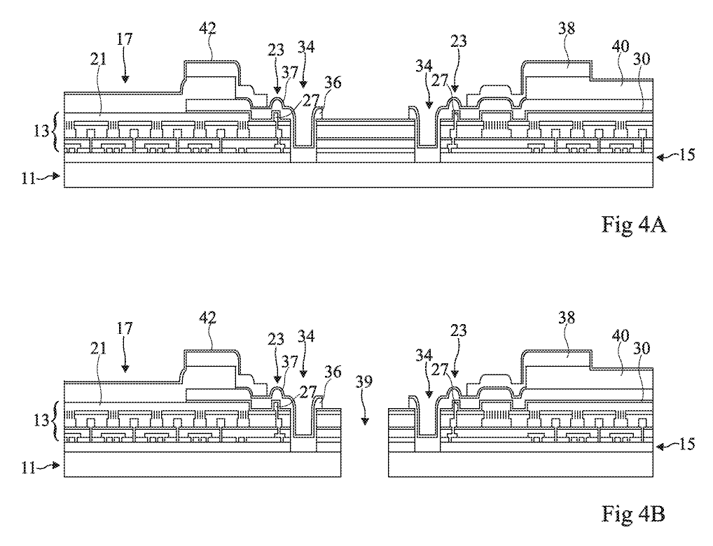

FIGS. 4A and 4B are sectional, partial and schematic views of structures obtained at the end of consecutive steps of an example method for manufacturing electronic chips according to a fourth embodiment.

The method for manufacturing electronic chips according to the fourth embodiment is similar to the method for manufacturing electronic chips according to the first embodiment with the difference that, in the fourth embodiment, the method comprises, before forming the encapsulation layer 38, forming a metal layer 40 on the top face of the nitride layer 37 formed at the surface of the insulating layer 36.

The method for manufacturing an electronic chip according to the fourth embodiment comprises exactly the steps described in relation to FIGS. 1A-F, which are not described again hereinafter.

FIG. 4A illustrates a structure obtained at the end of a step for etching the nitride layer 37, the metal layer 40, and the encapsulation layer 38 on the top face of the structure illustrated in FIG. 1F.

As an example, before depositing the metal layer 40, the layers 30 and 36 can be locally removed opposite the metal pads 21 so as to expose the top face of the metal pads 21, and ensure forming the metal layer 40 on and in contact with the pads 21.

After being deposited, the metal layer 40 is for example locally removed so as to be kept only at the desired locations for connecting to outer device(s).

The metal layer 40 is for example made of copper.

Further, the structure illustrated in FIG. 4A comprises a metal bump 42 or UBM (“Under Bump Metallization”). The bump 42 is for example formed on and in contact with the metal layer 40. The metal bump 42 is for example titanium-, nickel-, silver-, and/or gold-based. At the end of this step, the layer 38 is for example formed on and for example in contact with the metal layer 40. As an example, layer 38 is removed from openings 34. In addition, layer 38 can be removed in a portion between the peripheral openings 34 made around adjacent chips, opposite the future cutting paths individualizing the chips.

FIG. 4B illustrates a structure obtained at the end of a step for sawing the structure illustrated in FIG. 4A so as to form single electronic chips.

This step is identical to that described in relation with FIG. 1H. The encapsulation layer 38 is for example locally removed so as to let the top face of the metal layer 40 exposed.

Numerous applications are able to take advantage of the benefits provided by the electronic chop, this chip being thus integrable in various types of components.

As an example, the electronic chip can for example be integrated in a component intended to automotive industry. Electrifying motor vehicles causes a high increase in the number of electronic components in vehicles. The component comprises for example thyristors, rectifiers, high voltage transient voltage protection diodes, modules, etc. intended to be integrated within the vehicles. Furthermore, driving assistance and driving automation also cause an increase of the number of electronic components within vehicles.

As an example, the electronic chip could be integrated in a component intended to industry. More particularly, the component is for example used in developing green energies, or infrastructure electrification, for example for charge stations or in solar energy collection. The component could also be used in the fields of Internet of Things or smart home. For example, the component is intended to be implemented in circuits supplying power to equipment, for example including 30 V to 1200 V transistors. The component could also be used to implement computing systems in cloud, 5G RF communication networks, datacenters, and servers. For example, the component comprises broadband gap materials.

Various embodiments and variants have been described. Those skilled in the art will understand that certain features of these embodiments can be combined and other variants will readily occur to those skilled in the art. In particular, the second and fourth embodiments and the third and fourth embodiments could be combined.

Furthermore, the embodiments are limited neither to the example numeral values, nor to the example materials mentioned in the present disclosure.

Finally, the practical implementation of the embodiments and variants described herein is within the capabilities of those skilled in the art based on the functional description provided hereinabove.

1. A method for manufacturing electronic chips comprising:
a) forming an interconnection structure on a top face of a gallium-nitride-based stack, in turn arranged on a top face of a semiconductor substrate;
b) arranging a first insulating layer on the top face of the interconnection structure;
c) forming a resin etching mask on the top face of the first insulating layer, then etching the first insulating layer and the interconnection structure through the resin etching mask within a peripheral region of each electronic chip up to expose the top face of the gallium-nitride-based stack;
d) etching the gallium-nitride-based stack opposite the peripheral region using the first insulating layer as etching mask, up to expose the top face of the semiconductor substrate; and
e) cutting the semiconductor substrate so as to singularize the electronic chips.

2. The method for manufacturing electronic chips of claim 1, including, between steps d) and e), a step for forming a second insulating layer on the top face of the first insulating layer, and in a bottom and on one or more side flanks of the peripheral region.

3. The method for manufacturing electronic chips of claim 1, wherein the first insulating layer is made of an oxide.

4. The method for manufacturing electronic chips of claim 1, wherein the first insulating layer is deposited during step b) with a thickness in a range from 2 µm to 4 µm.

5. The method for manufacturing electronic chips of claim 1, wherein the interconnection structure has a thickness in a range from 10 µm to 15 µm.

6. The method for manufacturing electronic chips of claim 1, wherein each electronic chip includes a high electronic mobility transistor, the high electronic mobility transistor being formed within the interconnection structure, and in and on the gallium-nitride-based stack.

7. The method for manufacturing electronic chips of claim 1, wherein each electronic chip includes a seal ring.

8. The method for manufacturing electronic chips of claim 6, wherein the interconnection structure includes a metal pad, arranged on a flank of the top face of the interconnection structure, the metal pad being covered by the first insulating layer during step b).

9. The method for manufacturing electronic chips of claim 8, wherein the metal pad corresponds to a contact recovery pad of the high electronic mobility transistor.

10. The method for manufacturing electronic chips of claim 1, wherein etching the first insulating layer and the interconnection structure during step c) is an anisotropic etching, and etching the gallium-nitride-based stack during step d) is an anisotropic etching.

11. The method for manufacturing electronic chips of claim 1, wherein etching the first insulating layer and the interconnection structure during step c) is an isotropic etching, and etching the gallium-nitride-based stack during step d) is an anisotropic etching.

12. An electronic chip including:
an interconnection structure arranged on a top face of a gallium-nitride-based stack, in turn arranged on a top face of a semiconductor substrate; and
a first insulating layer on the top face of the interconnection structure,
the electronic chip further including, an opening in a peripheral region, exposing the top face of the semiconductor substrate.

13. The electronic chip of claim 12, wherein, in openings, side flanks of the interconnection structure are aligned with side flanks of the gallium-nitride-based stack.
